(19) United States
(12) Patent Application Publication
(10) Pub. No.: US 2005/0204554 A1
(43) Pub. Date: Sep. 22, 2005

(54) Method for processing electrical components, especially semiconductor chips, and device for carrying out the method

(76) Inventor: Georg Rudolf Sillner, Zeitlarn (DE)

Correspondence Address: HOFFMAN WASSON & GITLER, P.C;CRYSTAL CENTER 2, SUITE 522, 2461 SOUTH CLARK STREET, ARLINGTON, VA, 22202-3843, US

(21) Appl. No.: 10/508,948

(22) PCT Filed: Apr. 2, 2003
(86) PCT No.: PCT/DE03/01058

§ 371 Date: May 11, 2005

(30) Foreign Application Priority Data
Apr. 4, 2002 (DE) 102 14 969.0
Apr. 24, 2002 (DE) 102 18 384.8
Jun. 5, 2002 (DE) 102 25 097.9

(51) Int. Cl. H05K 3/30; B23P 19/00

(52) U.S. Cl. 29/834; 29/742

(57) ABSTRACT

The invention relates to a novel method for processing electrical components, especially semiconductor chips, which are respectively held in a detachable manner, as groups consisting of at least two components, by a first side thereof on a first carrier material of a first carrier.

### BACKGROUND OF THE INVENTION

Processes are known in the art for the manufacture of multiple semiconductor chips on a semiconductor wafer, which then, for further processing of the semiconductor chips, is releasably fastened on a carrier, i.e. on a carrier foil (blue foil) clamped in a carrier frame for removal at a later time, such that the electric connections, or contact surfaces of the chip, are located on the side of the wafer facing away from the carrier foil. Afterwards, the wafer is separated into the individual semiconductor chips, whereby the chips still adhere to the carrier foil.

For many applications, e.g. for technologies in which the contacts of the semiconductor chips should be established not by wire bonding, but directly with outer contacts, for example of a substrate or of a further semiconductor chip, it is necessary that the semiconductor chips be flipped, i.e. placed with their contact surfaces in front on the respective substrate or on contact surfaces located there. According to the state of the art, the chips for this purpose must be picked up individually on one side with a first pick-up element and removed from the carrier foil, and then for flipping, picked up with a second pick-up element on an opposite side and removed by the first pick-up element, and then, having been flipped, placed by the second pick-up element on a substrate, a further semiconductor chip and so on. This is inconvenient and time-consuming.

An object of the invention is to present a process that makes it possible to process a plurality of electric components, or semiconductor chips, together and thereby place them together on a carrier (second carrier).

### SUMMARY OF THE INVENTION

The processing of the components and preferably also the placing of the components, for example, take place together. If the processing causes the components to be flipped, then they can be further processed from the placing area in their already flipped form, or orientation by simple means, e.g. with conventional die bonders or similar devices.

“Processing”, according to the invention, in its simplest sense means the transport of the components. “Processing” according to the invention means especially also multiple flipping of the components and/or placing of the components, i.e. as a group of a plurality of components on a placing area, or a carrier.

“Placing area or carrier”, according to the invention, means generally any surface that is suitable for placing on, or putting down, components, especially a carrier foil, a belt, a transporter, or a board for receiving a plurality of components, etc.

“Multiple flipping”, according to the invention, means that a group of at least two components or chips, but for example an entire semiconductor wafer, already separated into individual chips but still held together on a carrier material or carrier foil (blue foil) is flipped and the individual components are then placed as an entire group or as part of a group or individually.

### BRIEF DESCRIPTION OF THE DRAWINGS

The invention is described below in detail based on exemplary embodiments with reference to the drawings, where:

FIG. 1 is a simplified principal representation of one embodiment of the invention;

FIG. 2 is a schematic representation of a section through a transfer element for use in the invention;

FIG. 3 is an single representation of a separating or transfer station;

FIG. 4 is a simplified representation in side view of a component or chip;

FIG. 5 is a partial representation of a section of an electric component with a chip located on a substrate or printed circuit board;

FIG. 6-8 show the separating and transfer station of a further embodiment of the invention in various working conditions and in a view corresponding to FIG. 3;

FIG. 9 is a schematic representation of the separating and transfer station of FIGS. 6-7 in a view perpendicular to the transport direction of the transport belt or transporter conveying the component or chip to this station, together with a further following transporter;

FIG. 10 is a top view of a partial length of the further transporter;

FIG. 11 is a perspective view of the transporter of FIGS. 9 and 10, together with a further transport element;

FIG. 12 is a simplified representation in top view of the transport belt with the components located there before the separating and transfer unit of FIGS. 6-8 in a further possible embodiment; and

FIGS. 13 and 14 show a top view and side view of a further possible embodiment of the transfer element for separating the carrier foil section carrying the components and for applying this carrier foil section with the components onto the transport belt of the transporter.

### DETAILED DESCRIPTION OF THE INVENTION

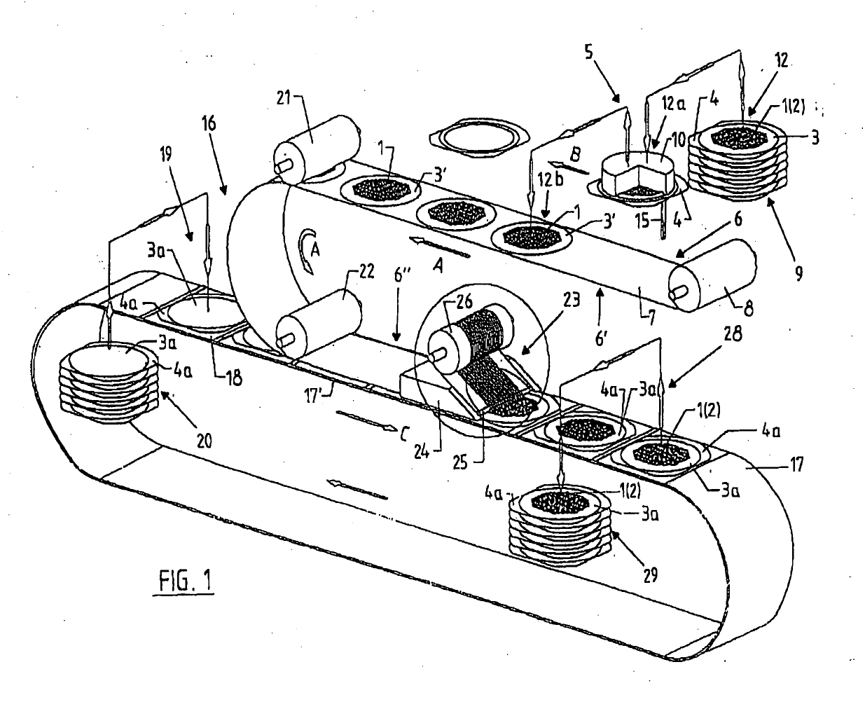

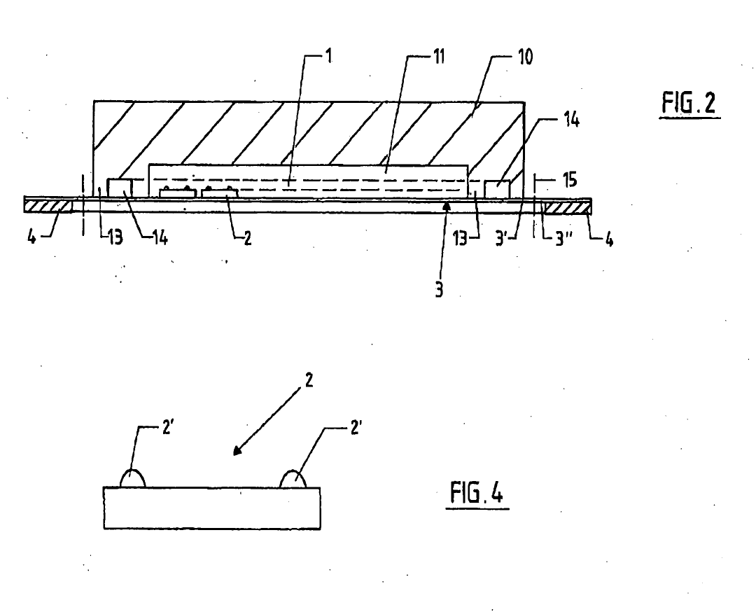

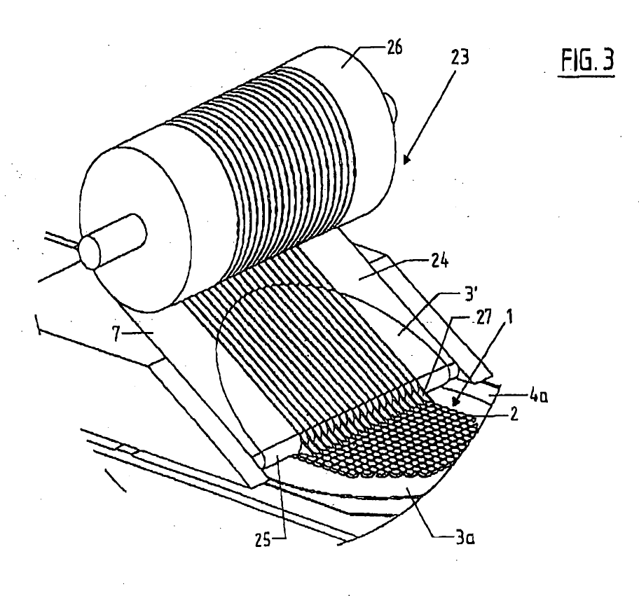

The process and the apparatus depicted in FIG. 1 are designed for the multiple flipping of semiconductor chips 2 formed by a semiconductor wafer 1 and already separated and held on a carrier foil 3 (blue foil) in a carrier frame 4 and, having been flipped, and for placing of the semiconductor chips 2 for further processing on a carrier foil 3a (blue foil) held in a carrier frame 4a, with maintaining the mutual arrangement or position of the chips as defined by the wafer.

While the semiconductor chips 2 originally are arranged on the carrier foil 3 so that the contact surfaces 2′ of the semiconductor chips 2 are located on the top side of the respective chip 2 facing away from the carrier foil 3—at the end of the process depicted in FIG. 1, which can also be designated as the flip-chip process—the semiconductor chips 2 are arranged on the carrier foil 3a so that they bear against the carrier foil 3a with that side which has the contact surfaces 2′. In this arrangement, further processing of the chips 2 is very simple, for example using a pick-and-place unit, e.g. for assembly of a PCB or a further semiconductor chip (chip-on-chip technology), in a die bonder, etc., namely in that the semiconductor chips 2 are placed with their contact surfaces 2′ on the conductor strips of the PCB, of the further semiconductor chip, etc., thus making a direct contact. The carrier foils 3 and 3a are made of a self-adhesive foil (blue foil), as used in semiconductor production.

To implement the flip-chip process, the wafers 1, which adhere to a sections 3′ of the carrier foil 3 and which are already separated into the individual semiconductor chips 2, are placed at a pick-up station 5 on a transporter 6 or its belt 7, such that the section 3′ of the carrier foil 3, which had been cut out with the wafer 1, lies with its bottom side facing away from the wafer 1 on the top of the transport belt 7. The transport belt 7 is formed by a belt-like transport foil that is self-adhesive on the top and can be used only once and is pulled off a supply roll 8 in the transport direction A of the transporter 6 by means of a drive not depicted.

The carriers (carrier foil 4 and carrier frame 4) wait as a stack 9 at the pick-up station 5. Furthermore, there is a pick-up and separating element 10 at the pick-up station 5 with a suction head 10′, which forms a recess 11 on its bottom side that is open toward this bottom side and otherwise closed. For accepting a wafer 1, the suction head 10′ is moved with its bottom side ahead from above against the carrier foil 3, with a wafer 1, of the uppermost carrier 4 in the stack 9 (pick-up position 12), so that the suction head 10′ or its aperture 11 completely accepts the wafer 1 and an edge area of the carrier foil 3 enclosing the wafer 1 bears against the edge 13 of the suction head bottom enclosing the opening of the recess 11. Afterwards, a vacuum is applied to the recess 11 and/or a ring-shaped groove 14 enclosing the recess 11 on the edge 13, so that the carrier foil 3 is sucked with its edge area enclosing the wafer 1 against the edge 13 of the suction head 10′.

The carrier foil 3 is then removed with the corresponding carrier frame 4 and the wafer 1 from the stack 9 and moved to a cutting position 12a, at which the section 3′ of the carrier foil 3 held to the suction head 10′ is separated by means of a cutting tool from the remainder 3″ extending radially over the suction head 10′ and thus also from the carrier frame 4, so that only the section 3′ with the wafer 1 is held on the suction head 10′. The carrier frames 4 with the carrier foil remainders 3″ are conveyed away from the cutting position 12a corresponding to the arrow B and supplied to a new application.

The carrier foil section 3′ carrying the wafer 1 is then placed with the suction head 10′ at the transfer position of the station 5 on the top of the section 6′ of the transporter 6 or of the transport belt 7 located there in a horizontal plane.

The transport belt 7 or the transport foil forming this transport belt is guided over a flipping area 16, which in the simplest form is formed by a deflecting pulley or roller rotating on a horizontal axis perpendicular to the transport direction A or an arch-shaped guide and on which the transport belt 7 is flipped so that the carrier foil sections 3′ with the wafers 1 are held suspended on the bottom of the transport belt 7 on the section 6″ of the transporter 6 following the flipping unit in transport direction A.

In the depicted embodiment, the length 6″ of the transporter 6 is in a horizontal plane, however beneath the length 6′. The upper length 17′ of an endless transport belt 17 is located beneath the length 6″ and parallel to the latter. The transport belt 17 is part of a second transporter and is driven endlessly and synchronously with the transport belt 7 such that a wafer 1 held hanging on the bottom of the length 6″ is consolidated with a carrier foil 3a located on the upper length 17′ or in a recess 18 there with its carrier frame 4a.

The carrier frame 4a with its carrier foils 3a are picked up from a stack 20 at a pick-up station by means of a pick-and-place element and placed in a retainer 18 of the transport belt 18.

In transport direction A before the flipping device 16 and after the flipping device 16, there are rollers 21 and 22, respectively. The roller 21 presses the wafer 1 and the carrier foil elements 3′ against the transport belt 7. The roller 22 presses the wafer 1 or the semiconductor chips 2 with their side facing away from the carrier foil element 3′ against the respective carrier foil 3a.

At a separating and transfer station 23 following the roller 22 in transport direction A of the transport belt 7, the wafer 1 or the semiconductor chips 2 are separated from the carrier foil elements 3′ in the manner that the semiconductor chips 2 remain on the respective carrier foil 3a. For this purpose, the separating and transfer station 23 has a deflector element 24 with a deflector edge 25 extending perpendicular to transport direction A and parallel to the plane of the transport belt 7 which (deflector edge) is deflected by nearly 180°, so that the chips 2 are released from the respective carrier foil 3′ while retaining their arrangement in the wafer 1. The semiconductor chips are then held releasably on the respective carrier foil 3a, while still retaining their original arrangement in the wafer 1. The transport belt 7 or the transport foil is rolled up into a roll 26 together with the carrier foil elements 3′ adhering to this transport foil after the deflection edge 25 for disposal.

In order to facilitate the release of the semiconductor chips 2 form the carrier foil elements 3′ at the deflector edge 25, a chamber-like structure is provided there that consists of a plurality of cutting edge-like projections 27. The projections 27 function to hold down the semiconductor chips 2 and prevent the semiconductor chips 2 from lifting off of the respective carrier foil 3a at the deflection edge 25. For this purpose, the projections 27 extend over the deflector edge 25 in transport direction C of the transport belt 17 and are arranged so that between the bottom of the projections 27 extending parallel or essentially parallel to the length 17′ of the transport belt 17 and the top of this transport belt 17 or the top of the respective carrier foil 3a, a guide gap for each semiconductor chip 2 is formed, the height of which gap is equal to or nearly equal to the thickness of the wafer 1.

So that the projections 27 can extend over the deflector edge 25 in the transport direction and that the transport belt 27 is still guided directly over the deflector edge 25, the projections 27 are designed as blades, which separate the transport belt 7 into a number of strips before it is rolled up onto the roll 26.

At a pick-up position 28 the carrier foils 3a held in their carrier frames 4a and equipped with the wafers 1 in flipped form are picked up from the transport band 17 and stacked for further processing (stack 29).

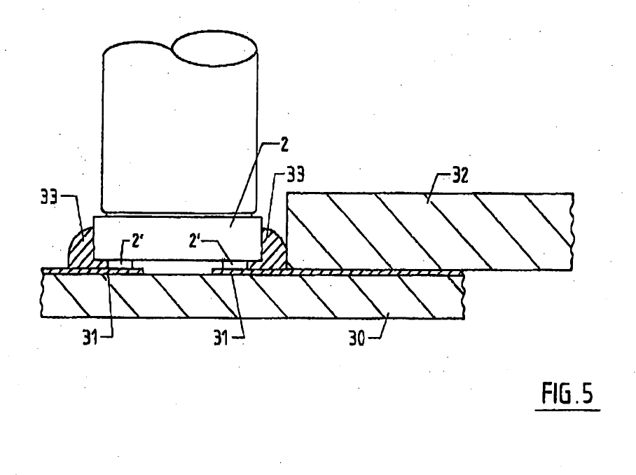

FIG. 4 shows in a very simplified representation and in cross section the mounting of the flipped semiconductor chip 2 on a substrate 30, which is manufactured from an insulating material in the form of a plate or platelet and is provided with contact surfaces and conductor strips at least on its top surface in FIG. 5, for example in the form of a structured metallization. The substrate 30 is made, for example of plastic or ceramic. The conductor strips 31 are connected with outer connections 32. After the flipping or flip-chip process described above the respective semiconductor chip 2 is removed at a corresponding station by means of a pick-and-place element not depicted from the flipped wafer 1 which has been placed on a carrier foil 3a held in a carrier frame 4a and then placed on the substrate 30 so that the chip contacts 2′ are in contact with the corresponding contact surfaces 31. The application of heat then causes bonding, i.e. soldering of the connections 2′ with the contact surfaces 31. For this purpose the contacts 2′ and/or the contact surfaces 31 are provided with a suitable solder. The semiconductor chip 2 is additionally anchored mechanically on the substrate 30 by means of an insulating mass 33, for example before bonding or soldering of the connections 2′ with the contact surfaces or conductor strips 31. The advantage lies for example in the fact that costly wire bonding for connecting the contact surfaces 2′ with their outer connections is eliminated.

The pick-and-place element for placing the respective semiconductor chip 2 in flipped form is for example part of a die bonder, with which the semiconductor chips 2 are placed on the substrates 30 that are pre-mounted in a leadframe and then connected with the conductor strips 31 of these substrates, whereby the outer connections 32 are then formed by fins of the leadframes.

The described technology can of course also be used to place a plurality of semiconductor chips 2 on one substrate 30, e.g. likewise in a leadframe, in order to manufacture a complex, integrated circuit. Of course, the described technology can also be used to mount the semiconductor chips 2 on a substrate, which in turn is formed by a semiconductor chip or an integrated circuit (chip-on-chip technology).

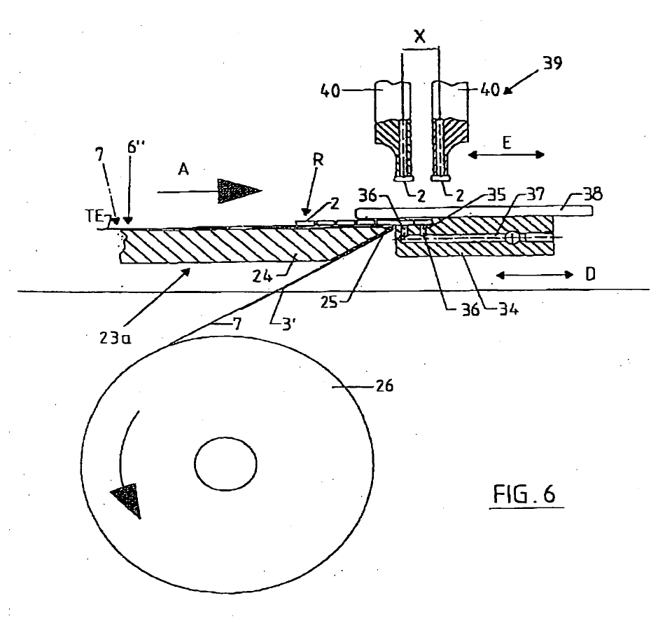

FIGS. 8-10 show a further possible embodiment of the invention. These drawings depict the transporter 6 with its section 6′ preceding the separating and transfer unit or station 23a. In this embodiment, the transporter 6 consists essentially of the self-adhesive transport foil or the self-adhesive transport belt 7, on which at specified intervals the carrier foil remainders 3′ with the semiconductor chips 2 adhering to them are transported to the separating and transfer unit 23, namely in transport direction A. The separating and transfer unit 23 comprises the deflector element 24 with the deflector edge 25 over which the transport belt 7 with the carrier foil sections 3′ is guided for removing the chips 2, whereby however in the embodiment of FIGS. 6-10 the roller 26 for rolling up the transport belt 7 that is no longer needed is located beneath the transport level of the section 6″ of the transporter 6. The carrier foil sections 3′ with the chips 2 are arranged on the transport belt 7 so that the chips are located on the side of the transport belt 7 or the carrier foil section 3′ facing away from the deflector element 24, namely corresponding to their arrangement on the semiconductor wafer 1 in a plurality of rows, which extend perpendicular to the transport direction A and in the depiction in FIGS. 6-8 also perpendicular to the plane of projection in this drawings and each of which has a plurality of chips 2. Furthermore, the chips in the individual rows are arranged congruently, i.e. each chip of a row R is located in a line parallel to transport direction A with a chip 2 of an adjacent row R.

A further component of the separating and transfer unit 23a is a placing element 34, which forms a placing area 35 following the deflector edge 25 in transport direction A, with a placing surface that is parallel or approximately parallel to the transport plane TE, which contains the transport belt 7 in the area of the deflector element 24 or the deflector edge 25, at the level of this transport plane or slightly below that level. The placing area formed by this placing surface is such that there is room for a specified number of chip rows R on the placing area 35, i.e. in the depicted embodiment, two rows R. The placing area 35 or the surface formed by the area is provided with vacuum openings 36, which are connected with a vacuum canal 37. The latter is connected by means of a valve not depicted for controlling the vacuum to the openings 36 with a vacuum or negative pressure source, also not depicted. By means of a drive that is not depicted the placing element 34 can furthermore be moved in an axis direction parallel to transport direction A by a specified horizontal stroke (double arrow D) from a starting position in which the placing area 35 connects nearly without gaps to the deflector element 24 in the area of the deflector edge 25 into a different position in which a there is a somewhat larger distance between the placing area 35 and the deflector edge 25.

In the depicted embodiment, the placing element 34 is formed by a rectangular plate, the surfaces of which are parallel to the transport plane TE and of which one longer peripheral side is parallel to the deflector edge 25, i.e. parallel to an axis in the transport plane T and extending perpendicular to transport direction A. The placing area 35 is formed by a recess on the top of the placing element 34, which (recess) is open toward this top side and toward the long side of the placing element 34 facing the deflector edge 25.

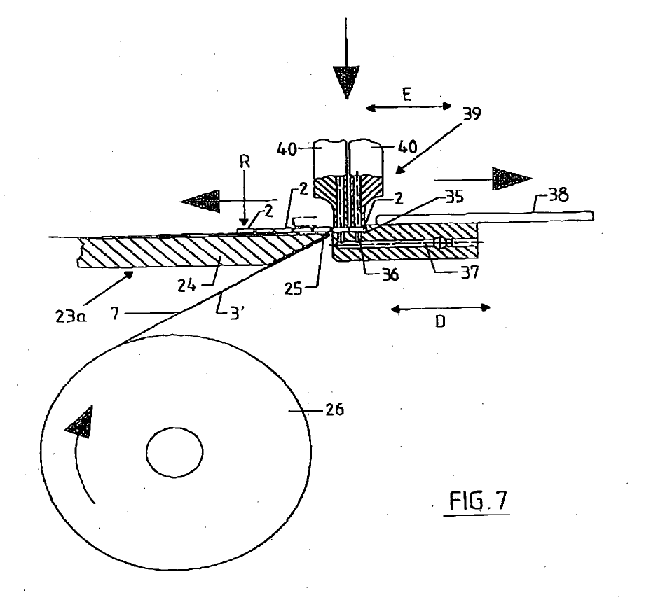

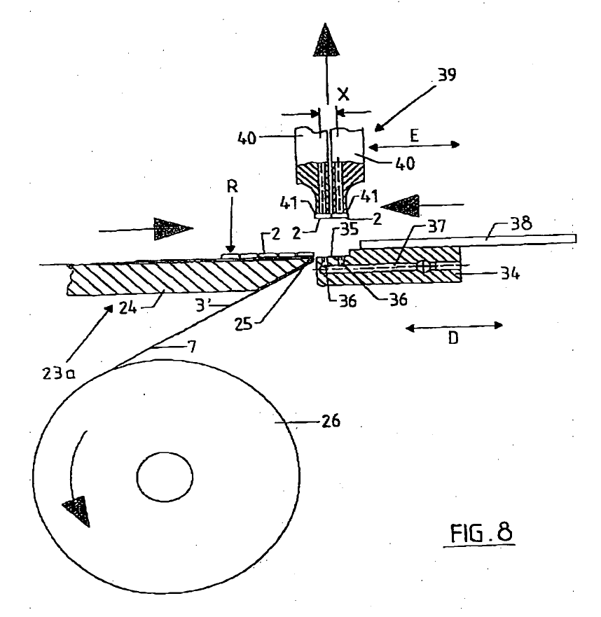

A further component of the separating and transfer unit 23a is a plate-shaped slider 38, which corresponding to the double arrow E can be moved in an axis direction parallel to transport direction A between a starting position and an end position, whereby the slider 38 in its starting position, which is depicted in FIG. 6, the deflector element 24 or the respective chip arrangement transported to the deflector edge 25 with the transport belt 7 on the top of these chips 2 covers a plurality of chips rows R that is at least equal to the number of chip rows R picked up from the placing area 35 and at the same time also covers the placing area 35. The slider 38 thus forms with its bottom side a guide for the chip rows R. When separating from the carrier foil elements 3′ and upon transfer to the placing area 35 in the end position, which is depicted in FIGS. 7 and 8, the slider 38 is pushed back so far that it also exposes the placing area 35.

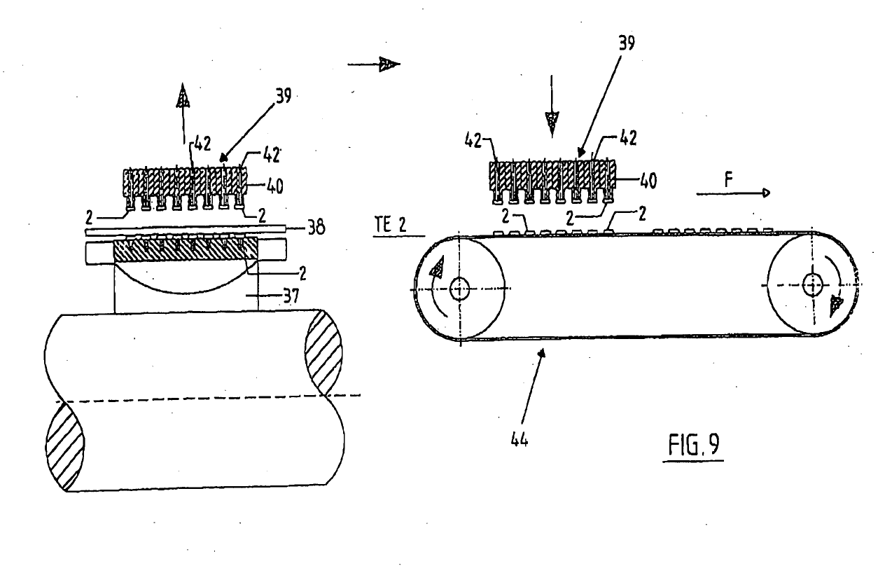

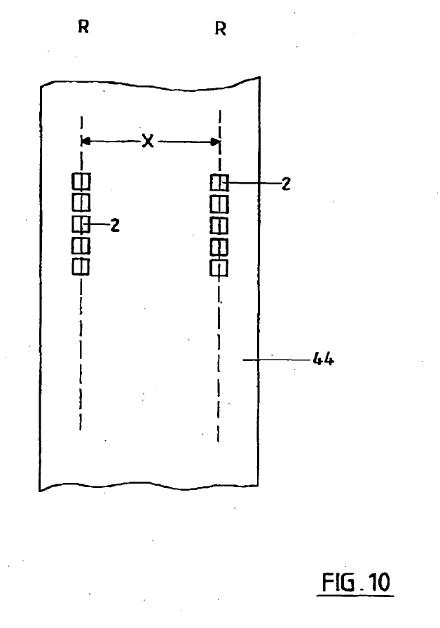

A further component of the separating and transfer unit 23a is a pick-up unit 39, which has two strip-shaped pick-up elements 40 or vacuum holders 40, with which in one step the two chip rows R waiting on the placing area 35 with the distance x there, are picked up and then the chips 2 of these rows are placed on a further transporter 41, on which the chips are held by adhesion, preferably by means of a vacuum and by which the chips 2 are supplied to a further application. As shown in FIGS. 9 and 10, the chip rows R are located one behind the other in transport direction F of this transporter 41, which is formed by an endless transport belt, always with two chip rows R crosswise to transport direction F at a distance from each other with the larger distance X and parallel to each other.

In the depicted embodiment the transport plane TE 41 of the transporter 41 is parallel to the transport plane TE 6 of the transporter 6. The transport directions A and F run parallel to each other.

The operation of the separating and transfer unit 23 can be described as follows: With the slider 38 in the starting position, the two front chip rows R in transport direction A are separated from the respective carrier foil element 3′ by moving the transport belt 7 over the deflection edge 25 and then pushed by the slider 38 onto the placing area 35. The placing element 34 is in its starting position during this time. Afterwards, the slider 38 is moved from its working position back into its non-working position and at the same time the placing element 34 is moved away from the deflection edge 35 by the stroke D, so that the distance between the two chip rows R placed on the placing area 35 and the front chip row R in transport direction A still on the carrier foil element 3′ in the proximity of the deflector edge 25 is increased somewhat. This condition is depicted in FIG. 7. Afterwards, the pick-up unit 39 is moved toward the placing area 35 so that one chip row R is picked up by the vacuum holder 40. By switching off the vacuum at the vacuum openings 36 the chip rows are taken along with the upwardly moving vacuum holders 40, as depicted in FIG. 8. After lifting, or during lifting, the two vacuum holders 40 are moved apart perpendicular to their longitudinal extension, so that the smaller distance x between the chip rows R on the transport belt 7 corresponding to the arrangement of the chips in the semiconductor wafer 1 is increased to the larger distance X (as in FIG. 6). In this condition the chip rows R are then placed on the transporter 41 by means of the vacuum holders 40. The larger distance X then corresponds for example to the machine distance of a following apparatus.

As indicated in FIG. 6, with the slider 38 moved back into the working position, two further chip rows R can be pushed onto the placing area 35 during the moving apart of the vacuum holders 40 or during the widening of the chip rows R held on these vacuum holders; the placing area then has also already moved back into its starting position.

During the above process, of course, the movements of the transport belt 7, the placing element 34, the slider 38, the pick-up unit 39 and the vacuum holders 40 relative to each other and also the movement of the transporters 41 are synchronized accordingly.

In addition to the vacuum holders 40, the longitudinal extensions of which are parallel to the transport plane TE 6 and perpendicular to the transport direction A, form a bearing surface 41 on their bottom side for the chips 2 of the chip rows R. Offset vacuum openings 42 are provided on the bearing surface 41 in the longitudinal direction of the vacuum holders 40.

A further component of the pick-up unit 39 is a pick-up head not depicted in the drawings, on which the vacuum holders 40 can be moved relative to each other in an axis direction perpendicular to their longitudinal extension and parallel to the transport plane TE 6, from a starting position, in which the vacuum holders 40 are essentially adjacent to each other and in which the distance of each vacuum opening 42 of one vacuum holder 40 to the adjacent vacuum opening 42 of the other vacuum holder is the smaller distance x, to a widened position in which the distance between adjacent vacuum openings 42 of the vacuum holders 40 is the larger distance X. The vacuum holders 40 are located on a head 43 of the pick-up unit 39, on which a drive for the widening of the vacuum holders 40 is provided and which in turn is connected with a drive for the controlled movement of the pick-up unit 39 or of the vacuum holders 40.

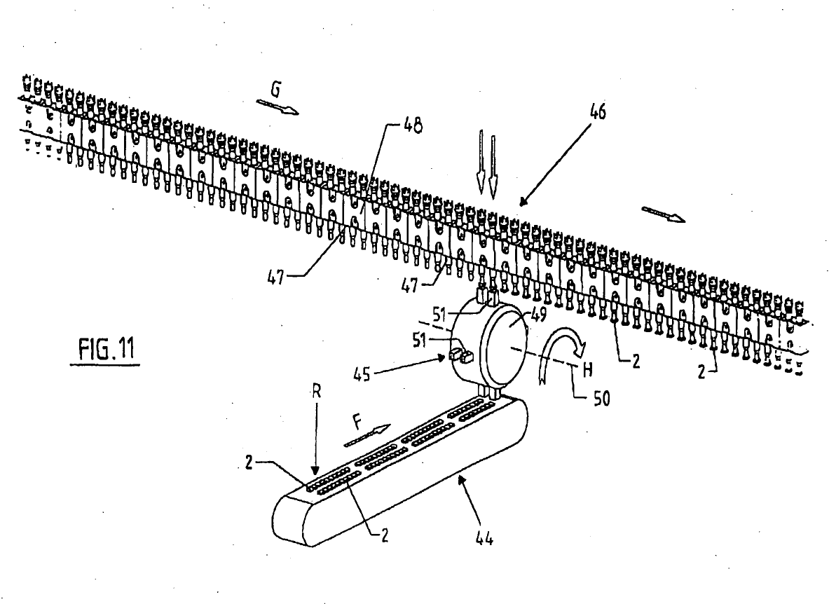

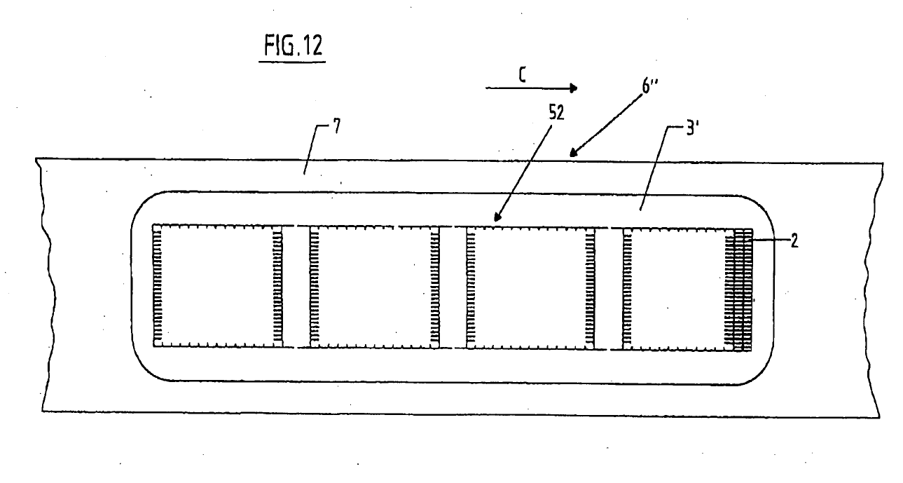

FIG. 11 again shows in a perspective view the transporter 44 consisting of an endless transport belt on which the two rows R of the components 2 are formed, which for example in this embodiment again are semiconductor chips or semiconductor components with such semiconductor chips. On the back end of the transporter 44 in transport direction P, one component 2 is removed from each row R by means of a flipping or transfer unit 45 and then the two components 2 are then transferred to a transporter 46 or vacuum holders 47 there moving in the direction of the arrow G, with one component 2 being transferred to one vacuum holder 47 following in transport direction G. These vacuum holders are located-on a belt-like transport element 48, of which only a partial length is depicted, but which forms a self-contained endless loop. Both the transporter 44 and the flipping unit 45, in addition to the transporter 46 are moved in a synchronized cycle.

The flipping unit 45 has a drum 49 (arrow H) rotating on a horizontal axis parallel to transport direction G, which (drum) is provided with vacuum holders 51 on its circumference that are offset by 90° on the drum axis 50, offset against each other in pairs in the direction of the drum axis 50. The vacuum holders 51 and also the vacuum holders 47 are controlled so that in each cycle two components 2 are picked up with the vacuum holders 51 from the transporter 44 and at the same time two components 2 held on the vacuum holders 50 are transferred to two vacuum holders 47. After two flipping steps the two components 2 picked up from the transporter 44 with the corresponding vacuum holders 51 are moved to the transporter 46 for transfer to the vacuum holders 47 there. The drum axis 50 is perpendicular to transport direction F.

FIG. 12 again shows the bottom view of the transport belt 7 in the section 6″ of the transporter 6, in transport direction C shortly before the separating and transfer unit 23a, in which the components or semiconductor chips 2 are picked up (peeled off) in rows from the carrier foil remainder 3′ and moved away by means of the pick-up unit 39, for example placed on the transporter 44. While in the embodiment described in FIGS. 6-10 the components or semiconductor chips 2 are arranged on the carrier foil remainder 3′ in a form corresponding to the arrangement of the semiconductor wafer 1, i.e. in an arrangement in which the rows R extending perpendicular to transport direction C have a different length, FIG. 12 shows an embodiment in which the components or semiconductor chips 2 are in a rectangular arrangement 57 on the carrier foil remainder 3′ and therefore on the transport belt 7, again in rows, which follow each other in transport direction C and extend perpendicular to this transport direction and are of the same length. The carrier foil remainder 3′ also has an essentially rectangular shape.

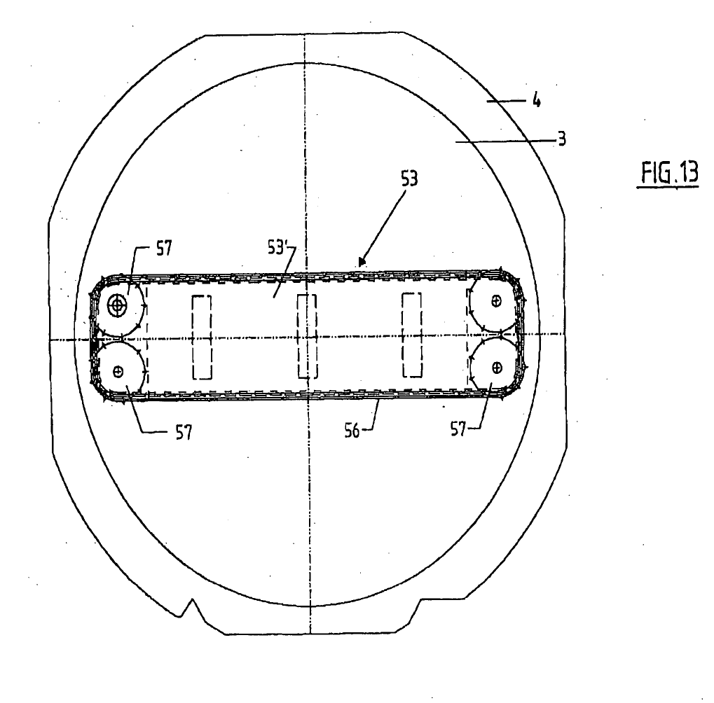

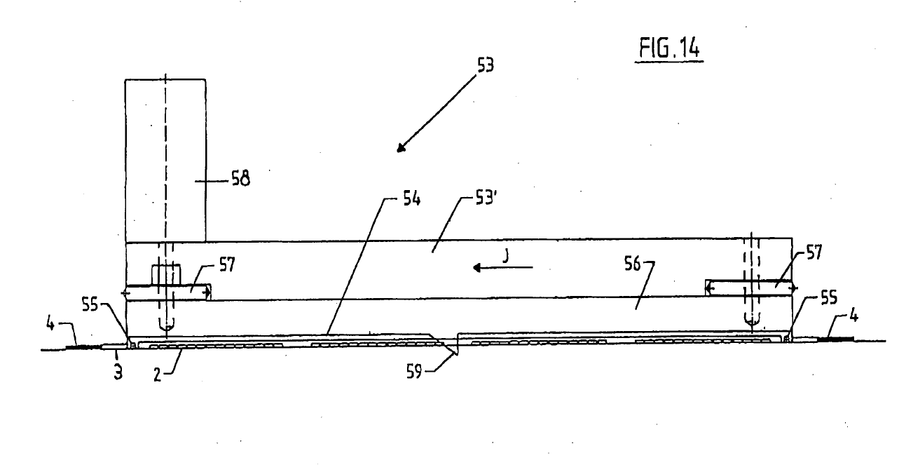

The advantage of this embodiment consists in the fact that in each work cycle of the pick-up unit corresponding to the pick-up unit 39, rows of the same length are transferred. FIGS. 13 and 14 illustrate in a simplified depiction the function of the separating and transfer element 53 corresponding to the separating and transfer element 10. The latter likewise consists essentially of a suction head 53′ with an open aperture 54 on the bottom of this suction head and an edge 55 that encloses this aperture and is provided with a seal. A controlled vacuum can be applied to the aperture 54. There, on the perimeter of the rectangular suction head with rounded corners there is an endless belt 56 that forms a closed loop and is guided on rollers 57, which are provided on each of the rounded corners of the suction head 53′. At least one roller 57 is driven by a drive 58, so that the belt 56 moved in the direction of the arrow 1. On the bottom long side of the belt 56 a cutting edge 59 is formed that projects over the plane of the bottom of the suction head 53′ defined by the edge 55.

To remove the components 2 from the carrier foil 3 held in the carrier frame 4, the suction head 53′ is lowered onto the top of the carrier foil 3 so that the section of the carrier foil 3 with the components 2 is held in the aperture 54, the depth of which is equal to or slightly larger than the height of the components or semiconductor chips 2. During the lowering of the suction head 53′ onto the carrier foil 3, the latter is already pierced by the cutting edge 59. Afterwards, a vacuum is applied to the aperture 54, so that the carrier foil 3 with the components or semiconductor chips there is held onto the suction head 53′ by means of vacuum. The components then bear against the bottom of the aperture 54 with the top side facing the carrier foil 3. Activating the drive 58 causes one full revolution of the belt 56 with the cutting edge 59, which then cuts through the carrier foil 3 at a separating line that is essentially rectangular corresponding to the arrangement of the components 2 and enclosing this separating line, by which the essentially rectangular carrier foil section 3′ is retained and can be placed on the transport belt 7.

The invention was described above based on exemplary embodiments. It goes without saying that numerous modifications and variations are possible without abandoning the underlying inventive idea of the invention.

### Reference Numbers

1 semiconductor wafer
2 semiconductor chip
3, 3a carrier foil (blue foil)
3′, 3″ carrier foil element or catch
4, 4a carrier frame
5 feed station
6 transporter
6′, 6″ section of transporter 6
7 transport belt or transport foil
8 supply roll for transport belt 6
9 stack of carrier frames 4 with carrier foils 3
10 separating and transfer element
10′ suction head
11 recess
12 pick-up position
12a cutting position
12b placing position
13 suction head edge
14 vacuum groove
15 cutting tool
16 flipping device
17 transport belt or transporter
17′ transport belt length
18 retainer
19 feed position
20 stack of carrier frames 4a with carrier foils 3a
21, 22 pressure roller
23, 23a separating and transfer unit
24 deflector element
25 deflector edge
26 roll
27 projection
28 removal position
29 stack of carrier frames 4a with carrier foils 3a and flipped wafers 1 or semiconductor chips 2
30 substrate
31 strip conductor or contact
32 outer connection
33 insulating and fastening mass
34 placing element
35 placing area
36 vacuum aperture
37 vacuum canal
38 auxiliary guide or slide
39 pick-up unit
40 multiple vacuum holder
41 bearing surface
42 vacuum aperture
43 head of pick-up unit
44 transporter
45 flipping and transfer unit
46 transporter
47 vacuum holder
48 transport element
49 drum
50 drum axis
51 vacuum holder
52 component arrangement

1. A process for processing electric components, the components are releasably held as a group of at least two components with a first side on a first carrier material of a first carrier, wherein the first carrier material is separated from the first carrier in an edge area not occupied by the components,
a section of the first carrier material with the components is placed on a first transporter and
the components are then removed or pulled off of the first carrier material for placing to a placing area.

2. The process according to claim 1, wherein the components are then removed from the first carrier material for placing on a placing area together.

3. The process according to claim 1, wherein the section of the first carrier material with the components is placed with a side facing away from the components on the first transporter.

4. The process according to claim 1, wherein the first carrier is a carrier frame with the first carrier material.

5. The process according to claim 1, wherein a second carrier is a second carrier material held in a second carrier frame.

6. The process according to claim 5, wherein the placing of the components on the second carrier takes place singly.

7. The process according to claim 5, wherein the placing of the components on the second carrier takes place as a group or sub-group.

8. The process according claim 1, wherein the group of at least two components is formed by a semiconductor wafer, which is separated into a plurality of semiconductor chips located on the first carrier material.

9. The process according to claim 1, wherein flipping of the components takes place on a transport belt forming the first transporter on which the components are moved by means of a flipping unit from a feed position to a separating and a transfer position.

10. The process according to claim 9, wherein the transport belt forming the first transporter is made of a self-adhesive transport foil.

11. The process according to claim 1, wherein the separation of the components at a separating or transfer position takes place in that a transport belt forming the first transporter is pulled off of the components held with their second side on a second carrier together with the sections of the first carrier material.

12. The process according to claim 11, wherein the removal by deflecting the transport belt forming the first transporter takes place at a deflection edge extending crosswise or perpendicular to a transport direction (A) of the first transporter.

13. The process according to claim 5, wherein the second carriers are provided on a second transporter at the separating and transfer position for transfer of each group of components to a separate second carrier.

14. The process according to claim 13, wherein the second carriers with the sections of the first carrier material or with the groups of components located on these sections are consolidated before reaching the separating and transfer station so that the components already bear with their second side against one of the second carriers when the separating and transfer station is reached.

15. The process according to claim 1, wherein with the use of first carriers in the form of a carrier frame and a carrier foil held in this carrier frame, the carrier foil is separated from the carrier frame by a separating device in an area surrounding the components and the section of the carrier foil with the components is placed on the first transporter.

16. The process according to claim 1, wherein the components are transferred at a separating or transfer position as at least one component row (R) to a placing area, from which the components are picked up by means of a pick-up unit.

17. The process according to claim 16, wherein at least two component rows (R) are transferred in one step at the separating and transfer position to the placing area.

18. The process according to claim 16, wherein a plurality of components of at least one component row (R) or components of a group of several components are picked up from the placing area simultaneously by the pick-up unit.

19. The process according claim 16, wherein at the placing area components of at least two component rows (R) are picked up simultaneously with the pick-up unit and that before placing the components the distance of the rows formed at the pick-up unit is increased.

20. The process according to claim 1, wherein the components on the first transporter in the transport direction (F) of this transporter all have the same length.

21. The process according to claim 1, wherein the components picked up by the first transporter are transferred by means of at least one transporter and/or one flipping unit to pick-ups of a third transporter.

22. The process according to claim 1, wherein a carrier foil remainder with the components is cut out of the carrier foil carrying the components, whereby the carrier foil remainder has a circular or rectangular or square profile.

23. An apparatus for processing electric components, which are releasably held as a group of at least two components with a first side on a first carrier material of a first carrier
comprising means for separating one section of the first carrier material carrying a group of components and for placing this section on a transport surface of a first transporter at a feed station,
whereby the first transporter or its transport surface can be moved between the feed station and a separation or transfer station, and
by means at the separating or transfer station for removing or separating the components from the section of the first carrier material carrying the components for placing the components on a placing area.

24. The apparatus according to claim 23, further comprising a separating or transfer station for single placing of the components on the second carrier takes place.

25. The apparatus according to claim 23, further comprising a separating or transfer station is designed so that the for the multiple placing of the components on the second carrier as a group or sub-group.

26. The apparatus according to claim 23, wherein the first transporter has a transport belt.

27. The apparatus according to claim 26, wherein the transport belt is self-adhesive on one side forming a transport surface.

28. The apparatus according claim 23, further comprising a second transporter for feeding a second carrier to the separating and transfer station.

29. The apparatus according to claim 23, wherein the first transporter is a self-adhesive transport belt, and further comprises means for deflecting the transport belt by at least 90° provided at the separating or transfer station for releasing the components from the transport belt or from the remainder of the first carrier material.

30. The apparatus according to claim 29, wherein the means for deflecting the transport belt are formed by a deflecting edge.

31. The apparatus according to claim 30, wherein projections are provided on the deflection edge that extend beyond the latter and function to hold down the components.

32. The apparatus according to claim 23, further comprising a placing area for at least one component row (R) and a pick-up element for picking up the components, for picking up the entire component row (R) or for the simultaneous pick-up of a component group comprising a plurality of components (2.

33. The apparatus according to claim 32, wherein the pick-up unit is formed by at least two holders and that the holders are moved relative to each other in order to increase a distance (x, X).

34. The apparatus according to claim 33, wherein each holder forms fixtures or bearing surfaces for several components.

35. The apparatus according to claim 33, wherein the holders are vacuum holders.

36. The apparatus according to claim 23, wherein the means for separating an element from the first carrier material carrying a group of components and for placing the element onto the transport surface of the first transporter are formed by a suction head with a cutting or separating unit.

37. The apparatus according to claim 36, wherein the cutting or separating unit is an endless driven belt with at least one cutting edge.

38. The apparatus according to claim 37, wherein the belt is guided over several rollers on the suction head (53′) to form an essentially rectangular or square loop.
